(19) United States
(12) Patent Application Publication
(10) Pub. No.: US 2016/0211145 A1
(43) Pub. Date: Jul. 21, 2016

(54) METHOD FOR ETCHING GROUP III-V SEMICONDUCTOR AND APPARATUS FOR ETCHING THE SAME

(71) Applicants: TOKYO ELECTRON LIMITED, Tokyo (JP); TOHOKU TECHNO ARCH CO., LTD., Miyagi (JP)

(72) Inventors: Xun Gu, Miyagi (JP); Yoshiyuki Kikuchi, Miyagi (JP); Seiji Samukawa, Miyagi (JP)

(73) Assignees: TOKYO ELECTRON LIMITED, Tokyo (JP); TOHOKU TECHNO ARCH CO., LTD., Miyagi (JP)

(21) Appl. No.: 15/000,458

(22) Filed: Jan. 19, 2016

(30) Foreign Application Priority Data
Jan. 20, 2015 (JP) 2015-008647

(51) Int. Cl. H01L 21/306; H01L 21/67; H01L 21/308

(52) U.S. Cl. CPC H01L 21/30621; H01L 21/3081; H01L 21/67069

(57) ABSTRACT

Disclosed is a method for etching a group III-V semiconductor, including irradiating, under an atmosphere of an organic gas, neutral particles to a group III-V semiconductor layer formed on a substrate to cause a complex reaction, thereby etching the group III-V semiconductor layer.

### CROSS-REFERENCE TO RELATED APPLICATIONS

This application is based on and claims priority from Japanese Patent Application No. 2015-008647 filed on Jan. 20, 2015 with the Japan Patent Office, the disclosure of which is incorporated herein in its entirety by reference.

### TECHNICAL FIELD

The present disclosure relates to a method for etching a group III-V semiconductor and an apparatus for etching the same.

### BACKGROUND

A group III-V semiconductors (also referred to as a “group III-V compound semiconductor”) is a direct transition type semiconductor, which is widely used in a light emitting diode, a laser diode, a photodiode, and the like. In a manufacturing process of a device using such a group III-V semiconductor, an etching processing has conventionally been performed using, for example, plasma of chlorine gas or CH₄/H₂ gas, which has been used in etching of an electrode layer (see, for example, Japanese Patent Laid-Open Publication No. 2003-282844).

### SUMMARY

According to an aspect, the present disclosure provides a method for etching a group III-V semiconductor, including irradiating, under an atmosphere of an organic gas, neutral particles to a group III-V semiconductor layer formed on a substrate to cause a complex reaction, thereby etching the group III-V semiconductor layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an explanatory view schematically illustrating a vertical section of an etching processing apparatus according to an exemplary embodiment.

FIG. 2 is an explanatory view schematically illustrating a SEM photograph when InGaAs is etched by an etching method according to the exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In such a method, since a material of a hard mask was limited due to the relationship with the kind of the processing gas of the plasma source, the selectivity was not sufficient, leading to a limit in a fine processing. In addition, when etching is performed using the plasma active species as they are, there is a concern about damage to the group III-V semiconductor layer on the substrate.

The present disclosure has been made in consideration of the problems described above, and an object of the present disclosure is to secure a high selectivity while suppressing damage when etching the group III-V semiconductor.

According to an aspect, the present disclosure provides a method for etching a group III-V semiconductor, including irradiating, under an atmosphere of an organic gas, neutral particles to a group III-V semiconductor layer formed on a substrate to cause a complex reaction, thereby etching the group III-V semiconductor layer.

According to the present disclosure, since etching is performed by irradiating, under an atmosphere of an organic gas, neutral particles to a group III-V semiconductor layer formed to cause a complex reaction, it is possible to realize a higher selectivity than that in a case where etching is performed using chlorine gas or halogen gas in the related art. Further, since neutral particles are irradiated, it is also possible to suppress damage.

The neutral particles may include those formed by neutralizing ions generated when converting hydrogen, argon gas, or other inert gases, or a mixed gas of two or more thereof, into plasma. That is, the ions in the plasma are drawn into a through-hole formed in a shielding unit, for example, an aperture (a member partitioning a plasma part and a neutral particle irradiation part), and as the ions collide with the wall surface of the hole in the aperture, the electrons are shifted so that the ions are neutralized, thereby becoming neutral particles, which may be used herein. In this case, respective neutral particles may be used which are neutralized as follows: positive ions are neutralized as electrons are shifted to the ions, and negative ions are neutralized as electrons are shifted to the aperture. Other available inert gases may be selected from, for example, He, Ne, and Xe gases.

A mask on the group III-V semiconductor layer at the time of the etching may be made of, for example, SiO₂, SiN, TiN, or Al.

The organic gas may be, for example, a CₓH_{y}O_{z}-based gas. Examples thereof may include alcohols such as ethanol and methanol, CH-based gases such as methane and ethane, and carboxylic acids (e.g., HCOOH or CH₃COOH).

According to another aspect, the present disclosure provides an apparatus for performing the above-described method. The apparatus includes a decompressible processing container including a plasma generating chamber in which plasma is generated, and a processing chamber in which the substrate is placed, the processing chamber being separated from the plasma generating chamber via a shielding unit. The plasma generating chamber is supplied with a gas for neutral particle generation. The processing chamber is supplied with an organic gas. The shielding unit includes a plurality of openings that communicate the plasma generating chamber and the processing chamber, and is configured to shield ultraviolet rays from plasma from being incident on the processing chamber.

In this case, the shielding unit may be connected with a power source for bias.

According to the present disclosure, it is possible to secure a high selectivity while suppressing damage when etching the group III-V semiconductor.

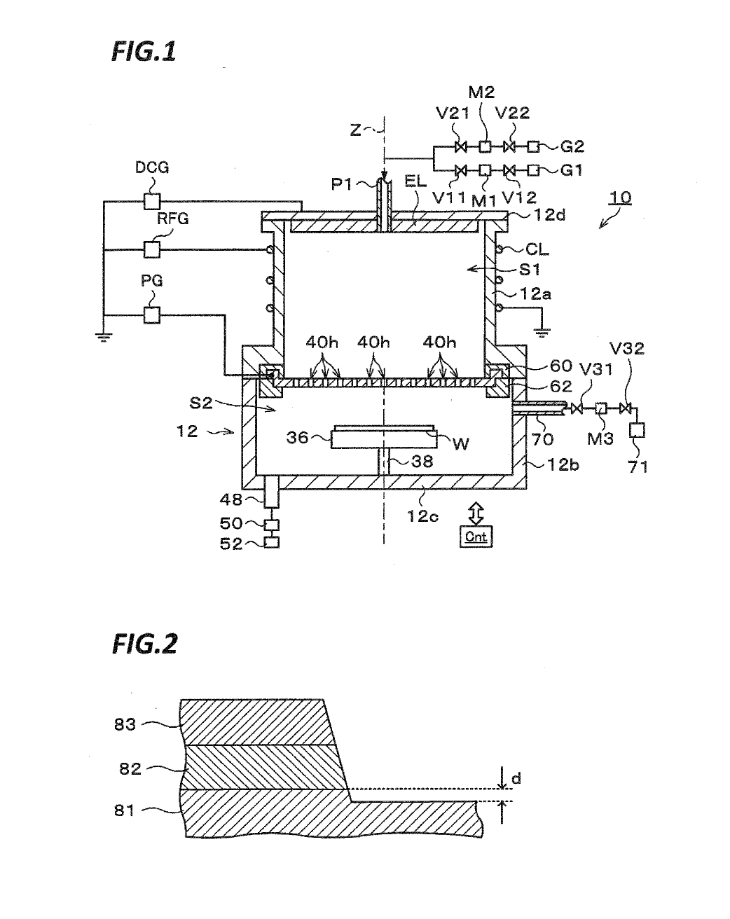

Hereinafter, an exemplary embodiment of the present disclosure will be described. FIG. 1 is a view illustrating an exemplary etching apparatus 10 according to an exemplary embodiment, and schematically illustrates a vertical section of the etching apparatus 10. The etching apparatus 10 includes a processing container 12. The processing container 12 is a substantially cylindrical container that extends in a direction where an axis Z extends (hereinafter, referred to as an “axis Z direction”), and includes a space defined therein. The space includes a plasma generating chamber S1 and a processing chamber S2 located below the plasma generating chamber S1.

In the exemplary embodiment, the processing chamber 12 includes a first sidewall 12a, a second sidewall 12b, a bottom portion 12c, and a cover portion 12d. The members constituting the processing container 12 are connected to the ground, and thus, they have a ground potential.

The first sidewall 12a has a substantially cylindrical shape extending in the axis Z direction, and defines the plasma generating chamber S1. The upper end of the first sidewall 12a is opened. The cover portion 12d is provided on the first sidewall 12a to close the opening of the first sidewall 12a. Further, a disc-shaped electrode plate EL is attached to the bottom surface of the cover portion 12d. The cover portion 12d and the electrode plate EL include a hole formed to penetrate through the cover portion 12d and the electrode plate EL along the axis Z. A pipe P1 passes through the hole to be connected to the plasma generating chamber S1.

The pipe P1 is connected with a gas source G1 via a valve V11, a flow rate controller M1 such as, for example, a mass flow controller, and a valve V12. Further, the pipe P1 is connected with a gas source G2 via a valve V21, a flow rate controller M2 such as, for example, a mass flow controller, and a valve V22. The gas source G1 is a source of a gas that contains hydrogen (hereinafter, referred to as a “hydrogen-containing gas”), for example, a source of hydrogen (H₂) gas. Further, the gas source G2 is a source of a rare gas, for example, a source of argon (Ar) gas. The etching apparatus 10 may selectively supply at least one of the hydrogen-containing gas from the gas source G1 and the rare gas from the gas source G2, to the plasma generating chamber S1.

A coil CL is wound around the outer periphery of the first sidewall 12a. One end of the coil CL is connected to the ground, and the other end of the coil CL is connected to a high frequency power source RFG. In the etching apparatus 10, an induced magnetic field may be generated in the plasma generating chamber S1 by supplying a power from the high frequency power source RFG to the coil CL. The gas supplied into the plasma generating chamber S1 may be excited by the induced magnetic field, so that plasma is generated in the plasma generating chamber S1.

The second sidewall 12b is provided below the first sidewall 12a described above to be continuous to the first sidewall 12a. The second sidewall 12b has a substantially cylindrical shape extending in the axis Z direction, and defines the processing chamber S2. The etching apparatus 10 includes a placing table 36 in the processing chamber S2. The placing table 36 is configured to support a substrate W serving as a workpiece on its top surface. In the exemplary embodiment, the placing table 36 is supported by a support 38 that extends from the bottom portion 12c of the processing container 12 in the axis Z direction. The placing table 36 includes an attraction and holding mechanism such as, for example, an electrostatic chuck, and a temperature controlling mechanism such as, for example, a coolant flow path connected to, for example, a chiller unit, or a heater (all not illustrated).

An exhaust pipe 48 passes through the bottom portion 12c of the processing chamber 12 to communicate with the processing chamber S2. The exhaust pipe 48 is connected with a pressure adjustor 50 and a decompression pump 52. The pressure adjustor 50 and the decompression pump 52 constitute an exhaust device. In the etching apparatus 10, the pressure adjustor 50 and the decompression pump 52 may be operated to adjust the flow rate of the gas supplied to the plasma generating chamber S1 and the flow rate of the gas supplied to the processing chamber S2, so that the pressure of the plasma generating chamber S1 and the pressure of the processing chamber S2 are adjusted.

In the etching apparatus 10, a shielding unit 40 is provided between the plasma generating chamber S1 and the processing chamber S2. The shielding unit 40 is formed of a substantially disc-shaped member. The shielding unit 40 includes a plurality of openings 40h that communicate the plasma generating chamber S1 and the processing chamber S2.

The shielding unit 40 is supported by, for example, the first sidewall 12a. In the exemplary embodiment, the peripheral portion of the shielding unit 40 is inserted between an insulating member 60 and an insulating member 62, so that the shielding unit 40 is supported by the first sidewall 12a through the insulating members 60, 62. Accordingly, in the exemplary embodiment, the shielding member 40 is electrically insulated from the first sidewall 12a.

The shielding unit 40 has a shielding property against ultraviolet rays generated in the plasma generating chamber S1. That is, the shielding unit 40 is formed of a material that does not transmit ultraviolet rays. Further, in the exemplary embodiment, when the ions generated in the plasma generating chamber S1 are reflected on the inner wall surface that defines the opening 40h and pass through the opening 40h, the shielding unit 40 donates electrons to the ions. Therefore, the shielding unit 40 neutralizes the ions and releases the neutralized ions, that is, neutral particles to the processing chamber S2. In the exemplary embodiment, the shielding unit 40 may be formed of, for example, silicon. Further, without being limited thereto, the shielding unit 40 may be formed of a hardly oxidized material, for example, a member made of aluminum, a member made of aluminum of which the surface is anodized, or a member made of aluminum of which the surface is provided with a yttria film.

In the exemplary embodiment, the shielding unit 40 may be connected with a bias power source PG that applies a bias power to the shielding unit 40. The bias power source PG may be a high frequency power source that generates a high frequency bias power. Alternatively, the bias power source PG may be a DC power source. When a power is applied to the shielding unit 40 by the bias power source PG, the ions generated in the plasma generating chamber S1 are accelerated toward the shielding unit 40. As a result, the speed of the particles passing though the shielding unit 40 is increased.

In the exemplary embodiment, the electrode plate EL may be connected to a DC power source DCG. Even when a DC voltage is applied to the electrode plate EL by the DC power source DCG, the ions generated in the plasma generating chamber S1 may be accelerated toward the shielding unit 40.

The second sidewall 12b, which is a sidewall of the processing chamber S2, is provided with an organic gas supply unit 70. The organic gas supply unit 70 is connected with an organic gas source 71 via a valve V31, a flow rate controller M3 such as, for example, a mass flow controller, and a valve V32. In the exemplary embodiment, ethanol (C₂H₅OH) is prepared in the organic gas source 71. In addition, the organic gas source 71 is provided with a heating device (not illustrated), so that a volatilized organic gas may be adjusted to a predetermined temperature.

As illustrated in FIG. 1, in the exemplary embodiment, the etching apparatus 10 includes a controller Cnt. The controller Cnt may be constituted by a control device such as, for example, a programmable computer device. The controller Cnt may control respective parts of the etching apparatus 10 according to a program based on a recipe.

For example, the controller Cnt transmits a control signal to the valves V11, V12 to control the supply of the hydrogen-containing gas from the gas source G1 and the stop of the supply, and transmits a control signal to the flow rate controller M1 to control the flow rate of the hydrogen-containing gas from the gas source G1. Further, the controller Cnt transmits a control signal to the valves V21, V22 to control the supply of the rare gas from the gas source G2 and stop of the supply, and transmits a control signal to the flow rate controller M2 to control the flow rate of the rare gas from the gas source G2. Further, the controller Cnt transmits a control signal to the valves V31, V32 to control the supply of the organic gas from the organic gas source 71 and the stop of the supply, and transmits a control signal to the flow rate controller M3 to control the flow rate of the organic gas from the organic gas source 71.

Further, the controller Cnt may transmit a control signal to the pressure adjustor 50 to control the exhaust amount. Further, the controller Cnt may transmit a control signal to the high frequency power source RFG to adjust the high frequency power, and transmits a control signal to the bias power source PG to control the supply of the bias power to the shielding unit 40 and the stop of the supply. Further, the controller Cnt may transmit a control signal to the temperature controlling mechanism (not illustrated) of the placing table 36 to adjust the temperature of the substrate W.

The etching apparatus 10 according to the exemplary embodiment is configured as described above. Next, descriptions will be made on an exemplary etching method using the etching apparatus 10.

The substrate W is first accommodated in the processing chamber S2, and then placed on the placing table 36. Then, the hydrogen-containing gas and the argon gas, which is a rare gas serving as a plasma excitation gas, are supplied to the plasma generating chamber S1 from the gas sources G1, G2, respectively. Then, the high frequency power is applied from the high frequency power source RFG to the coil CL. Thus, plasma of the hydrogen-containing gas is generated in the plasma generating chamber S1. When active species, for example, ions of the hydrogen in the plasma pass through the shielding unit 40, the active species are neutralized, so that the processing chamber S2 is supplied with neutral particles of the hydrogen atoms. Meanwhile, the processing chamber S2 is supplied with an organic gas, that is, ethanol from the organic gas source 71 which is adjusted to a predetermined temperature.

Due to this, a complex reaction occurs in the group III-V semiconductor formed on the substrate W. That is, assuming that the group III-V semiconductor is X, and the energy of the neutral particles is KE, the following complex reaction occurs:

X+C₂H₅OH(+H₂)+KE→X(C₂H₅)₃↑+H₂O

Since the group III-V semiconductor may be etched in this way, and furthermore, the group III-V semiconductor is etched by the complex reaction, the degree of freedom of a material to be used as a hard mask is high, and a high selectivity may be obtained even with SiN or SiO₂ which has been used as a mask material for the conventional group III-V semiconductor. Further, since the etching is performed by the complex reaction as described above, there is no UV irradiation, and thus, there is no damage to the substrate, as compared with a general method of performing etching with active species of plasma of a fluorine-based gas. Therefore, the damage to the group III-V semiconductor is also much smaller than that in the conventional method. Further, a gas such as, for example, He, Ne, or Xe may be used in place of the argon gas.

Next, descriptions will be made on examples in which etching is performed on InGaAs that is a group III-V semiconductor, using the etching apparatus 10 illustrated in FIG. 1.

[Hydrogen Neutral Particle Treatment]

Flow rate of processing gas: H₂/Ar=20/100 sccm

Power of high frequency power source PFG: 800 W

Power of bias power source PG: 0 W

Pressure in processing container 12: 0.32 Pa

Temperature of substrate W: 50° C.

Excitation time: 15 minutes

[Etching Processing by Neutral Particles]

The following steps (1) and (2) were repeated alternately 12 times.

Step (1)

Flow rate of processing gas: H₂/Ar=20/100 sccm

Power of high frequency power source PFG: 800 W

Power of bias power source PG: 15 W

Pressure in processing container 12: 0.32 Pa

Temperature of substrate W: 50° C.

Processing time: 3 minutes

Step (2)

Flow rate of processing gas: C₂H₅OH/Ar=25/100 sccm

Power of high frequency power source PFG: 800 W

Power of bias power source PG: 20 W

Pressure in processing container 12: 0.37 Pa

Temperature of substrate W: 50° C.

Temperature of C₂H₅OH: 60° C.

Processing time: 5 minutes

The result of the example will be described with reference to FIG. 2. FIG. 2 is an explanatory view schematically illustrating a SEM photograph when an InGaAs layer 18 was etched using a TiN layer 82 and an Al layer 83 as hard masks. As a result, the InGaAs layer 81 was etched until a depth d becomes 31 nm. On the other hand, as for the TiN layer 82 and the Al layer 83, the shape and thickness remained almost exactly. Therefore, according to the example, it has been found that a high selectivity was realized with the TiN layer 82 and the Al layer 83 as hard masks.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for etching a group III-V semiconductor, the method comprising:
irradiating, under an atmosphere of an organic gas, neutral particles to a group III-V semiconductor layer formed on a substrate to cause a complex reaction, thereby etching the group III-V semiconductor layer.

2. The method of claim 1, wherein the neutral particles are formed by neutralizing ions generated when converting hydrogen, argon gas, or other inert gases, or a mixed gas of two or more thereof, into plasma.

3. The method of claim 1, wherein a mask on the group III-V semiconductor layer at the time of the etching is made of SiO₂, SiN, TiN, or Al.

4. The method of claim 1, wherein the organic gas is a CₓH_{y}O_{z}-based gas.

5. An apparatus for performing the method claimed in claim 1, the apparatus comprising:
a decompressible processing container including a plasma generating chamber in which plasma is generated, and a processing chamber in which the substrate is placed, the processing chamber being separated from the plasma generating chamber via a shielding unit,
wherein the plasma generating chamber is supplied with a gas for neutral particle generation,
the processing chamber is supplied with an organic gas, and
the shielding unit includes a plurality of openings that communicate the plasma generating chamber and the processing chamber, and is configured to shield ultraviolet rays from plasma from being incident on the processing chamber.

6. The apparatus of claim 5, wherein the shielding unit is connected with a power source for bias.
